(19) United States
(12) Patent Application Publication
(10) Pub. No.: US 2025/0248045 A1
(43) Pub. Date: Jul. 31, 2025

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Jongho Woo, Suwon-si (KR); Seung Min Lee, Suwon-si (KR); Moonkang Choi, Suwon-si (KR); Sangwoo Han, Suwon-si (KR)

(21) Appl. No.: 18/782,476

(22) Filed: Jul. 24, 2024

(30) Foreign Application Priority Data
Jan. 26, 2024 (KR) 10-2024-0012566

(51) Int. Cl. H10B 51/30; H10B 51/20

(52) U.S. Cl. CPC H10B 51/30; H10B 51/20

(57) ABSTRACT

A three-dimensional semiconductor memory device includes a substrate, a stacked structure including gate electrodes stacked on the substrate in a first direction perpendicular to a lower surface of the substrate, a semiconductor pattern extending in the stacked structure in the first direction, a back gate plug extending in the first direction in the semiconductor pattern, a back gate plate extending on a upper surface of the back gate plug in a second direction and a third direction parallel to the lower surface of the substrate, and having an opening therein, a bit line on the back gate plate, and a selection channel structure electrically connecting the bit line and the semiconductor pattern, wherein the selection channel structure is in the opening.

### CROSS-REFERENCE TO RELATED APPLICATIONS

This U.S. non-provisional patent application claims priority under 35 U.S.C. § 119 to Korean Patent Application No. 10-2024-0012566 filed on Jan. 26, 2024, in the Korean Intellectual Property Office, the entire contents of which are hereby incorporated by reference.

### BACKGROUND

The inventive concept relates generally to semiconductor memory devices, and, more particularly, to a three-dimensional semiconductor memory device and an electronic system including the same.

A need may arise to have a semiconductor device capable of storing a large amount of data in an electronic system which may need data storage. Semiconductor devices have been highly integrated to meet high performance and low manufacturing cost, which are desired by customers. Integration of typical two-dimensional or planar semiconductor devices is primarily determined by the area occupied by a unit memory cell, such that it is greatly influenced by the level of technology for forming fine patterns. However, the expensive processing equipment needed to increase pattern fineness may set a practical limitation on increasing the integration of the two-dimensional or planar semiconductor devices. Therefore, there have been proposed three-dimensional semiconductor memory devices having three-dimensionally arranged memory cells.

### SUMMARY

An object of the inventive concept is to provide to a three-dimensional semiconductor memory device with improved reliability and productivity and an electronic system including the same.

The problems to be solved by the inventive concept is not limited to the problems mentioned above, and other problems not mentioned will be clearly understood by those skilled in the art from the description below.

A three-dimensional semiconductor memory device according to some embodiments of the inventive concept may include a substrate, a stacked structure including gate electrodes stacked on the substrate in a first direction perpendicular to a lower surface of the substrate, a semiconductor pattern penetrating (i.e., extending into) the stacked structure and extending in the first direction, a back gate plug extending in the first direction in the semiconductor pattern, and a back gate plate extending on a upper surface of the back gate plug in a second direction and a third direction parallel to a lower surface of the substrate, and having an opening therein, a bit line on back gate plate, and a selection channel structure electrically connecting the bit line and the semiconductor pattern, wherein the selection channel structure is disposed in the opening.

A three-dimensional semiconductor memory device according to some embodiments of the inventive concept may include a substrate, a stacked structure including gate electrodes stacked on the substrate in a first direction perpendicular to a lower surface of the substrate, a ferroelectric layer and a semiconductor pattern penetrating the stacked structure and extending in the first direction in the stacked structure, a back gate plug extending in the first direction in the semiconductor pattern, and a back gate plate extending in a second direction and a third direction parallel to the lower surface of the substrate, on a upper surface of the back gate plug, wherein the semiconductor pattern includes a vertical portion extending in the first direction and a horizontal portion extending further in a horizontal direction than the vertical portion, on the vertical portion, and the back gate plate includes an opening that at least partially vertically overlaps the horizontal portion of the semiconductor pattern.

A electronic system according to some embodiments of the inventive concept may include a three-dimensional semiconductor memory device and a controller electrically connected to the three-dimensional semiconductor memory device through at least one input/output pad and controlling the three-dimensional semiconductor memory device, wherein the three-dimensional semiconductor memory device includes a substrate, a stacked structure including gate electrodes stacked on the substrate in a first direction perpendicular to a lower surface of the substrate, a semiconductor pattern penetrating the stacked structure and extending in the first direction, a back gate plug extending in the first direction in the semiconductor pattern, a back gate plate extending on a upper surface of the back gate plug in a second direction and a third direction parallel to the lower surface of the substrate, and having an opening therein, a bit line on the back gate plate, and a selection channel structure electrically connecting the bit line and the semiconductor pattern, and the selection channel structure is disposed in the opening.

### BRIEF DESCRIPTION OF THE DRAWINGS

Example embodiments will be more clearly understood from the following brief description taken in conjunction with the accompanying drawings, wherein like reference numerals (when used) indicate corresponding elements throughout the several views. The accompanying drawings represent non-limiting, example embodiments as described herein.

FIG. 1A is a diagram schematically showing an electronic system including a three-dimensional semiconductor memory device according to comparative examples of the inventive concept.

FIG. 1B is a diagram schematically showing an electronic system including a three-dimensional semiconductor memory device according to some embodiments of the inventive concept.

FIG. 2 is a perspective view schematically showing an electronic system including a three-dimensional semiconductor memory device according to some embodiments of the inventive concept.

FIG. 3 is a cross-sectional view schematically illustrating a semiconductor package including a semiconductor device according to some embodiments of the inventive concept, and corresponds to a cross-section taken along line I-I′ of FIG. 2.

FIG. 4 is a cross-sectional view schematically illustrating a semiconductor package including a semiconductor device according to some embodiments of the inventive concept, and corresponds to a cross-section taken along line II-II′ of FIG. 2.

FIG. 5 is a plan view schematically showing a three-dimensional semiconductor memory device according to some embodiments of the inventive concept.

FIG. 6 is a cross-sectional view schematically illustrating the semiconductor device of FIG. 5 taken along line A-A′.

FIGS. 7 to 19 are diagrams schematically showing intermediate processes in an example method of manufacturing a three-dimensional semiconductor memory device according to some embodiments of the inventive concept.

### DETAILED DESCRIPTION

Hereinafter, a semiconductor device and a method of manufacturing the same according to embodiments of the inventive concept will be described in detail with reference to the drawings.

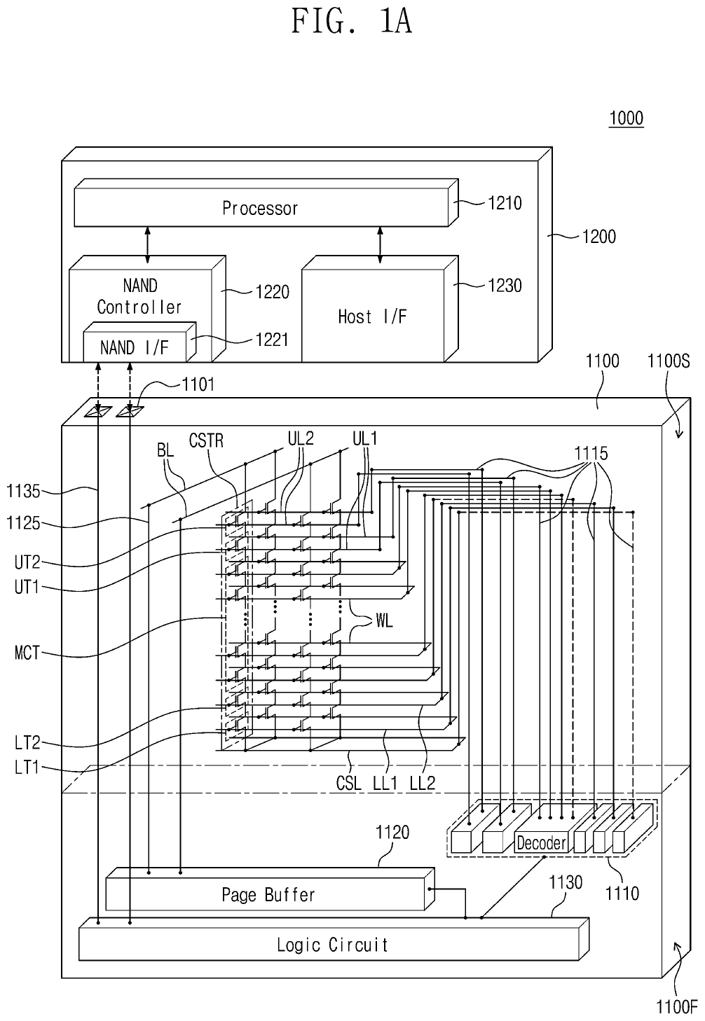

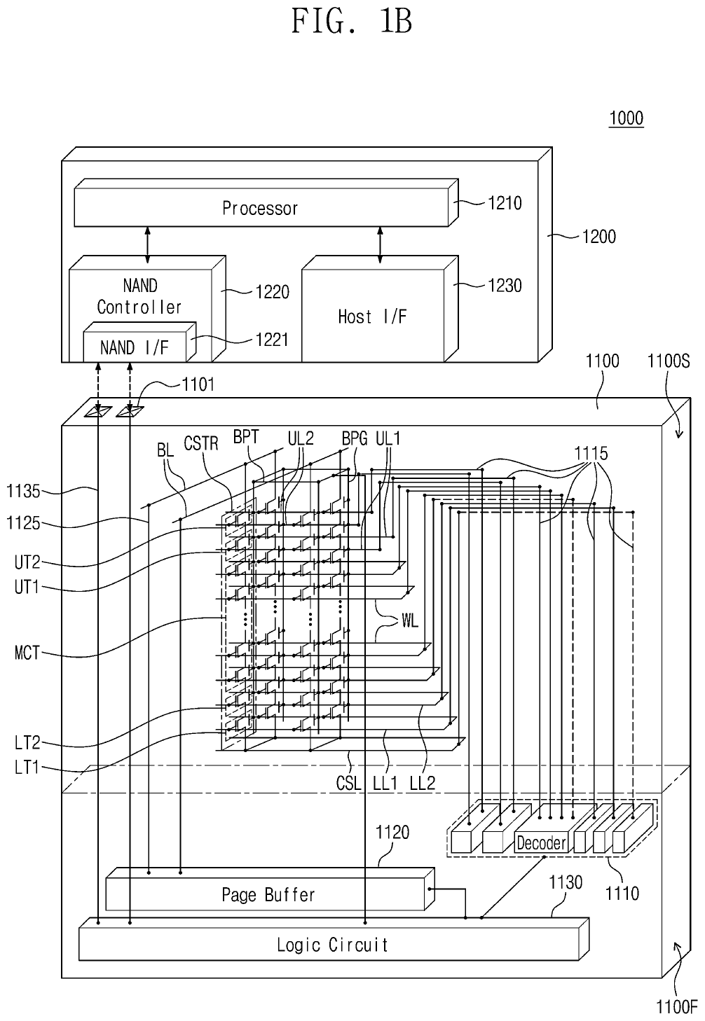

FIG. 1A is a diagram schematically showing an electronic system including a three-dimensional semiconductor memory device according to comparative examples of the inventive concept.

Referring to FIG. 1A, an electronic system 1000 according to an embodiment of the inventive concepts may include a three-dimensional semiconductor memory device 1100 and a controller 1200 electrically connected to the three-dimensional semiconductor memory device 1100. The electronic system 1000 may be a storage device that includes a single or a plurality of three-dimensional semiconductor memory devices 1100 or may be an electronic device that includes the storage device. For example, the electronic system 1000 may be a solid-state drive (SSD) device, a computing system, a medical apparatus, or a communication apparatus, each of which includes a single or a plurality of three-dimensional semiconductor memory devices 1100.

The three-dimensional semiconductor memory device 1100 may be a non-volatile memory device, such as a three-dimensional NAND Flash memory device which will be discussed below. The three-dimensional semiconductor memory device 1100 may include a first region 1100F and a second region 1100S on the first region 1100F. Meanwhile, different from that shown, the first region 1100F may be disposed on a side of the second region 1100S. The first region 1100F may be a peripheral circuit region that includes a decoder circuit 1110, a page buffer 1120, and a logic circuit 1130. The second region 1100S may be a memory cell region that includes bit lines BL, a common source line CSL, word lines WL, first lines LL1 and LL2, second lines UL1 and UL2, and memory cell strings CSTR between the bit line BL and the common source line CSL.

On the second region 1100S, each of the memory cell strings CSTR may include first transistors LT1 and LT2 adjacent to the common source line CSL, second transistors UT1 and UT2 adjacent to the bit lines BL, and memory cell transistors MCT disposed between the first transistors LT1 and LT2 and the second transistors UT1 and UT2. The number of the first transistors LT1 and LT2 and of the second transistors UT1 and UT2 may be variously changed in accordance with embodiments.

For example, the second transistors UT1 and UT2 may include a string selection transistor, and the first transistors LT1 and LT2 may include a ground selection transistor. The first lines LL1 and LL2 may be gate electrodes of the first transistors LT1 and LT2, respectively. The word lines WL may be gate electrodes of the memory cell transistors MCT, and the second lines UL1 and UL2 may be gate electrodes of the second transistors UT1 and UT2, respectively.

For example, the first transistors LT1 and LT2 may include a first erase control transistor LT1 and a ground selection transistor LT2 that are connected in series. For example, the second transistors UT1 and UT2 may include a string selection transistor UT1 and a second erase control transistor UT2 that are connected in series. One or both of the first and second erase control transistors LT1 and UT2 may be employed to perform an erasure operation in which a gate induced drain leakage (GIDL) phenomenon is used to erase data stored in the memory cell transistors MCT, but the inventive concept is not limited thereto.

The common source line CSL, the first lines LL1 and LL2, the word lines WL, and the second lines UL1 and UL2 may be electrically connected to the decoder circuit 1110 through first connection lines 1115 that extend from the first region 1100F toward the second region 1100S. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. The bit lines BL may be electrically connected to the page buffer 1120 through second connection lines 1125 that extend from the first region 1100F toward the second region 1100S.

On the first region 1100F, the decoder circuit 1110 and the page buffer 1120 may perform a control operation to at least one selection memory cell transistor among the plurality of memory cell transistors MCT. The logic circuit 1130 may control the decoder circuit 1110 and the page buffer 1120. The three-dimensional semiconductor memory device 1100 may communicate with the controller 1200 through at least one input/output pad 1101 electrically connected to the logic circuit 1130. The input/output pad 1101 may be electrically connected to the logic circuit 1130 through a corresponding at least one input/output connection line 1135 that extends from the first region 1100F toward the second region 1100S.

The controller 1200 may include a processor 1210, a NAND controller 1220, and a host interface (I/F) 1230. According to some embodiments, the electronic system 1000 may include a plurality of three-dimensional semiconductor memory devices 1100, and in this case, the controller 1200 may control the plurality of three-dimensional semiconductor memory devices 1100.

The processor 1210 may control overall operations of the electronic system 1000 including the controller 1200. The processor 1210 may operate based on predetermined firmware, and may control the NAND controller 1220 to access the three-dimensional semiconductor memory device 1100. The NAND controller 1220 may include a NAND interface 1221 that processes communication with the three-dimensional semiconductor memory device 1100. The NAND interface 1221 may be used to transfer therethrough a control command to control the three-dimensional semiconductor memory device 1100, data which is intended to be written on the memory cell transistors MCT of the three-dimensional semiconductor memory device 1100, and/or data which is intended to be read from the memory cell transistors MCT of the three-dimensional semiconductor memory device 1100. The host interface 1230 may provide the electronic system 1000 with communication with an external host (not explicitly shown). When a control command is received through the host interface 1230 from an external host, the three-dimensional semiconductor memory device 1100 may be controlled by the processor 1210 in response to the control command.

FIG. 1B is a diagram schematically showing an electronic system including a three-dimensional semiconductor memory device according to some embodiments of the inventive concept.

Referring to FIG. 1B, an electronic system 1000 including a three-dimensional semiconductor memory device according to some embodiments of the inventive concept may include the same/similar configuration to that of the electronic system 1000 described with reference to FIG. 1A.

In contrast, the second region 1100S of the electronic system 1000 including the three-dimensional semiconductor memory device according to some embodiments of the inventive concept may further include a back gate plate BPT. In addition, in the second region 1100S, each of the memory cell strings CSTR may further include a back gate plug BPG that is horizontally adjacent to the first transistors LT1 and LT2, the second transistors UT1 and UT2, and the memory cell transistors MCT.

The back gate plate BPT may be electrically connected to the logic circuit 1130 through a separate connection wiring extending from the first region 1100F to the second region 1100S.

The back gate plug BPG and the back gate plate BPT may be spaced apart from and electrically insulated from the common source line CSL, the bit lines BL, and the word line WL.

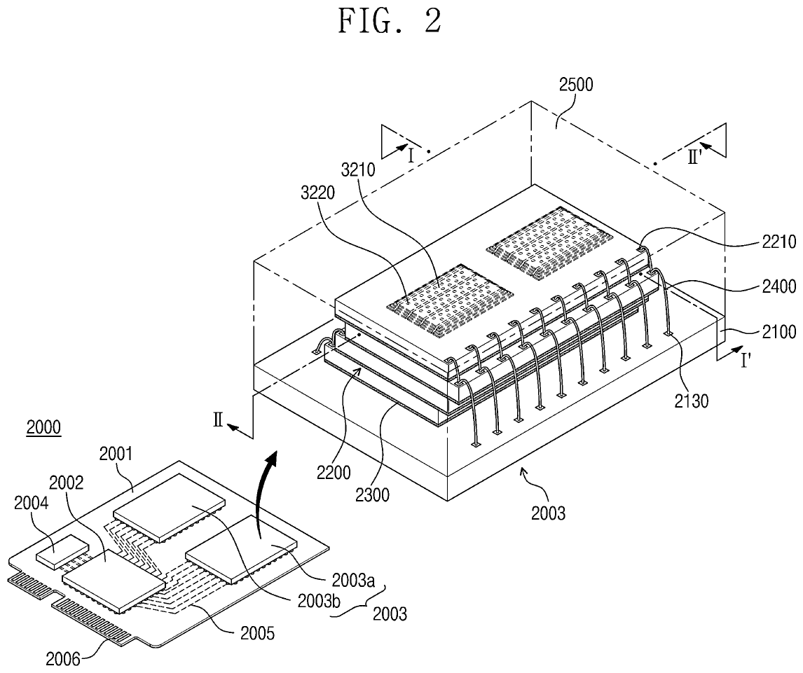

FIG. 2 is a perspective view schematically showing an electronic system including a three-dimensional semiconductor memory device according to some embodiments of the inventive concept.

Referring to FIG. 2, an electronic system 2000 according to an embodiment of the inventive concepts may include a main board 2001, a controller 2002 mounted on the main board 2001, one or more semiconductor packages 2003, and a dynamic random access memory (DRAM) 2004. The semiconductor package(s) 2003 and the DRAM 2004 may be connected to the controller 2002 through wiring patterns 2005 provided in the main board 2001.

The main board 2001 may include a connector 2006 including a plurality of pins which are provided to have connection with an external host (not explicitly shown). The number and arrangement of the plurality of pins on the connector 2006 may be changed based on a communication interface between the electronic system 2000 and the external host. The electronic system 2000 may communicate with the external host through one or more interfaces, for example, universal serial bus (USB), peripheral component interconnect express (PIC-Express), serial advanced technology attachment (SATA), and/or M-PHY for universal flash storage (UFS), although embodiments are not limited thereto. For example, the electronic system 2000 may operate with power supplied through the connector 2006 from the external host. The electronic system 2000 may further include a power management integrated circuit (PMIC) that distributes the power supplied from the external host to the controller 2002 and the semiconductor package 2003.

The controller 2002 may write data to the semiconductor package 2003, may read data from the semiconductor package(s) 2003, or may increase an operating speed of the electronic system 2000.

The DRAM 2004 may be a buffer memory that reduces a difference in speed between the external host and the semiconductor package(s) 2003 that serves as a data storage space. The DRAM 2004 included in the electronic system 2000 may operate as a cache memory, and may provide a space for temporary data storage in a control operation of the semiconductor package 2003. When the DRAM 2004 is included in the electronic system 2000, the controller 2002 may include not only a NAND controller for control of the semiconductor package(s) 2003, but a DRAM controller for control of the DRAM 2004.

The semiconductor package(s) 2003 may include a first semiconductor package 2003a and a second semiconductor package 2003b that are spaced apart from each other on the main board 2001. Each of the first and second semiconductor packages 2003a and 2003b may include a plurality of semiconductor chips 2200. Each of the first and second semiconductor packages 2003a and 2003b may include a package substrate 2100, semiconductor chips 2200 on the package substrate 2100, adhesive layers 2300 on bottom surfaces of the semiconductor chips 2200, connection structures 2400 that electrically connect the semiconductor chips 2200 to the package substrate 2100, and a molding layer 2500 that lies on the package substrate 2100 and covers or overlaps the semiconductor chips 2200 and the connection structures 2400.

The package substrate 2100 may be an integrated circuit board including package upper pads 2130. Each of the semiconductor chips 2200 may include input/output pads 2210. The input/output pads 2210 may correspond to the input/output pads 1101 of FIGS. 1A and 1B. Each of the semiconductor chips 2200 may include gate stack structures 3210 and memory channel structures 3220. Each of the semiconductor chips 2200 may include a three-dimensional semiconductor memory device which will be discussed below.

The connection structures 2400 may be, for example, bonding wires that electrically connect the input/output pads 2210 to the package upper pads 2130. Therefore, on each of the first and second semiconductor packages 2003a and 2003b, the semiconductor chips 2200 may be electrically connected to each other in a wire bonding manner, and may be electrically connected to the package upper pads 2130 of the package substrate 2100. In some embodiments, on each of the first and second semiconductor packages 2003a and 2003b, the semiconductor chips 2200 may be electrically connected to each other using through-silicon vias (TSVs) instead of the connection structures 2400 or the bonding wires.

Differently from that shown in FIG. 2, the controller 2002 and the semiconductor chips 2200 may be included in a single package. The controller 2002 and the semiconductor chips 2200 may be mounted on a separate interposer substrate other than the main board 2001, and may be connected to each other through wiring lines provided in the interposer substrate.

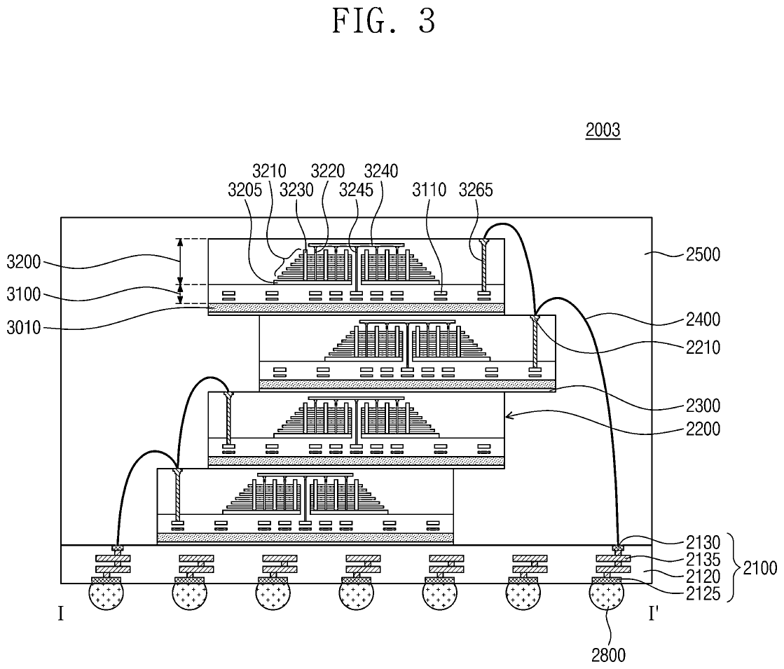

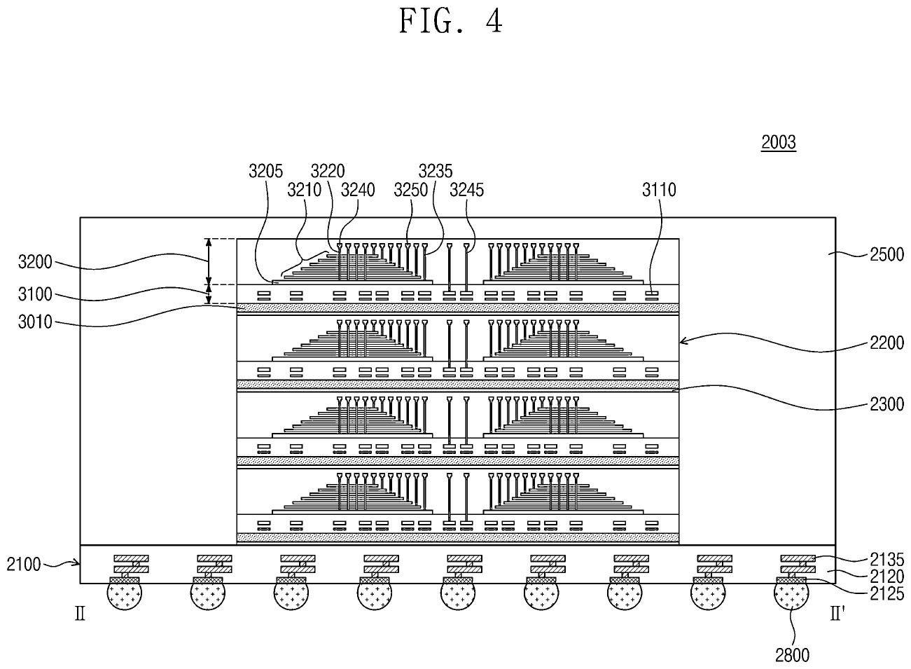

FIGS. 3 and 4 are cross-sectional views schematically illustrating a semiconductor package including a semiconductor device according to some embodiments of the inventive concept, and correspond to cross-sections taken along lines I-I′ and II-II′ of FIG. 2, respectively.

Referring to FIGS. 3 and 4, a semiconductor package 2003 may include a package substrate 2100, a plurality of semiconductor chips 2200 on the package substrate 2100, and a molding layer 2500 that covers or overlaps the package substrate 2100 and the plurality of semiconductor chips. The term “overlap” (or “overlapping,” or like terms), as may be used herein, is intended to broadly refer to a first element that intersects with at least a portion of a second element in the vertical direction (i.e., a direction perpendicular to an upper surface of the substrate), but does not require that the first and second elements be completely aligned with one another in a horizontal plane. The term “cover” (or “covering,” “covers,” or like terms), as may be used herein, is intended to broadly refer to an element, structure or layer that is on or over another element, structure or layer, either directly or with one or more other intervening elements, structures or layers therebetween.

The package substrate 2100 may include a package substrate body 2120, package upper pads 2130 on an upper surface of the package substrate body 2120, package lower pads 2125 disposed or exposed on a lower surface of the package substrate body 2120, and internal wiring lines 2135 that lie in the package substrate body 2120 and electrically connect the package upper pads 2130 to the package lower pads 2125. The package upper pads 2130 may be electrically connected to connection structures 2400. The package lower pads 2125 may be connected through conductive connectors 2800 to the wiring patterns 2005 in the main board 2001 of the electronic system 2000 depicted in FIG. 2.

Each of the semiconductor chips 2200 may include a semiconductor substrate 3010 and a first structure 3100 and a second structure 3200 that are sequentially stacked on the semiconductor substrate 3010. The first structure 3100 may include a peripheral circuit region including peripheral wirings 3110. The second structure 3200 may include a common source line 3205, a gate stacked structure 3210 on the common source line 3205, vertical channel structures 3220 penetrating (i.e., extending in) the gate stacked structure 3210, separation structures 3230, bit lines 3240 electrically connected to the vertical channel structures 3220, gate connection wirings 3235 and conductive lines 3250 electrically connected to the word lines WL (e.g., in FIG. 1B) of the gate stacked structure 3210.

As an example, the back gate plug BPG described with reference to FIG. 1B may be provided in the vertical channel structures 3220. As an example, a back gate plate BPT may be provided on the gate stacked structure 3210 and may be electrically connected to a back gate plug BPG.

Each of the semiconductor chips 2200 may include a through wiring 3245 that is electrically connected to the peripheral wirings 3110 of the first structure 3100 and extends into the second structure 3200. The through wiring 3245 may penetrate the gate stacked structure 3210 and may be further disposed outside the gate stacked structure 3210. Each of the semiconductor chips 2200 may further include an input/output connection wiring 3265 that is electrically connected to the peripheral wirings 3110 of the first structure 3100 and extends into the second structure 3200, and input/output pads 2210 electrically connected to the input/output connection wiring 3265.

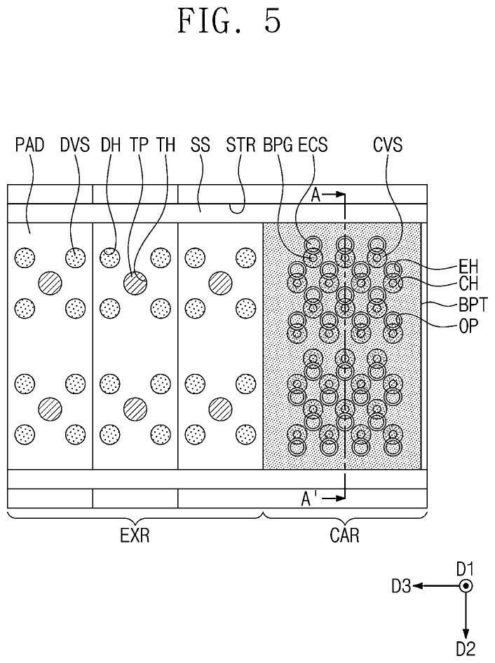

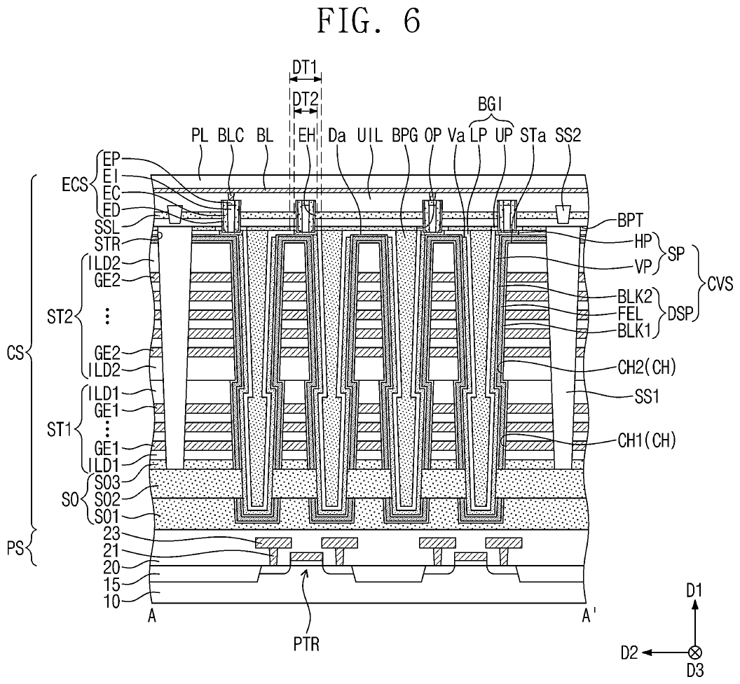

FIG. 5 is a plan view schematically showing a three-dimensional semiconductor memory device according to some embodiments of the inventive concept. FIG. 6 is a cross-sectional view schematically depicting the semiconductor memory device of FIG. 5 taken along line A-A′.

Referring to FIGS. 5 and 6, a three-dimensional semiconductor memory device according to some embodiments of the inventive concept may include a peripheral circuit structure PS and a cell array structure CS stacked on a substrate 10 in a first direction D1 (i.e., vertically) perpendicular to an upper surface of the substrate 10. The substrate 10 may correspond to the semiconductor substrate 3010 of FIGS. 3 and 4. The peripheral circuit structure PS may correspond to the first structure 3100 of FIGS. 3 and 4. The cell array structure CS may correspond to the second structure 3200 of FIGS. 3 and 4.

The substrate 10 may be, for example, a silicon substrate, a silicon-germanium substrate, a germanium substrate, or a single crystalline epitaxial layer grown on a monocrystalline silicon substrate, although embodiments are not limited thereto. The upper surface of the substrate 10 may be parallel to each of second and third directions D2 and D3, respectively, that intersect each other. For example, the first to third directions D1, D2, and D3 may be orthogonal to each other. A device isolation layer 15 may be provided in the substrate 10. The device isolation layer 15 may define an active region of the substrate 10.

The peripheral circuit structure PS may include peripheral transistors PTR on substrate 10, peripheral contact plugs 21, peripheral circuit wirings 23 electrically connected to peripheral transistors PTR through the peripheral contact plugs 21, and a first insulating layer 20 surrounding them. The term “surrounding” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

The peripheral transistors PTR may be provided on the active region of the substrate 10. The peripheral circuit wirings 23 may correspond to the peripheral circuit wirings 3110 of FIG. 3 or 4. The peripheral transistors PTR may constitute, for example, the decoder circuit 1110 (in FIG. 1B), the page buffer 1120 (in FIG. 1B), and the logic circuit 1130 (in FIG. 1B). Each of the peripheral transistors PTR may be, for example, an N-channel metal-oxide-semiconductor (NMOS) transistor or a P-channel metal-oxide-semiconductor (PMOS) transistor. The peripheral contact plugs 21 and peripheral circuit wirings 23 may include a conductive material such as metal.

The first insulating layer 20 may include a plurality of insulating layers having a multilayer structure. As an example, the first insulating layer 20 may include at least one of silicon oxide, silicon nitride, silicon oxynitride, and a low dielectric material. In this specification, a low dielectric material is defined as a material having a lower dielectric constant than silicon oxide.

A cell array structure CS may be provided on the peripheral circuit structure PS. The cell array structure CS may include a source layer SO and a stacked structure ST sequentially stacked on the peripheral circuit structure PS, a selection channel structure ECS on the stacked structure ST and a bit line BL on the selection channel structure ECS.

The source layer SO may include a first source layer SO1, a second source layer SO2, and a third source layer SO3 sequentially stacked on the peripheral circuit structure PS. The first to third source layers SO1, SO2, and SO3 may include a conductive material. As an example, the first to third source layers SO1, SO2, and SO3 may include polysilicon. As an example, the second source layer SO2 may correspond to the common source line 3205 in FIGS. 3 and 4.

The stacked structure ST may be provided on the third source layer SO3. As an example, a second insulating layer (not shown) may be provided on the first source layer SO1. The second insulating layer may surround the stacked structure ST. The second insulating layer may include a plurality of insulating layers having a multilayer structure.

The stacked structure ST may be provided in the plural. For example, when viewed in a plan view, the plurality of stacked structures ST may be spaced apart from each other in the second direction D2 and may each extend in the third direction D3. Hereinafter, for convenience of explanation, a single stacked structure ST will be described, but the following description may be equally applied to other stacked structures ST. The stacked structure ST may correspond to the gate stacked structure 3210 of FIGS. 3 and 4.

The stacked structure ST may include a first stacked structure ST1 and a second stacked structure ST2 sequentially stacked on the source layer SO. The first stacked structure ST1 may include first interlayer insulating layers ILD1 and first gate electrodes GE1 that are alternately stacked, and the second stacked structure ST2 may include second interlayer insulating layers ILD2 and second gate electrodes GE2 that are alternately stacked.

As an example, the first and second gate electrodes GE1 and GE2 may include at least one of a doped semiconductor (e.g., doped silicon, etc.), a metal (e.g., tungsten, copper, aluminum, etc.), a conductive metal nitride (e.g., titanium nitride, tantalum nitride, etc.) and transition metals (e.g., titanium, tantalum, etc.). As an example, the first and second interlayer insulating layers ILD1 and ILD2 may include at least one of silicon oxide, silicon nitride, silicon oxynitride, and a low dielectric material.

Although not shown, when viewed in a cross-sectional perspective view, the stacked structure ST may have a stepped structure in the third direction D3 on a cell array extension region EXR. That is, a thickness of the stacked structure ST in the cell array extension region EXR in the first direction D1 may decrease as a distance from the cell array region CAR increases. For example, a length of the first and second gate electrodes GE1 and GE2 in the third direction D3 may decrease as a distance from the substrate 10 increases. Each of the first and second gate electrodes GE1 and GE2 may include a pad portion PAD at one end in the third direction D3. The pad portion may be a region of each of the first and second gate electrodes GE1 and GE2 constituting the step portion of the stacked structure ST.

The through plug TP may penetrate (i.e., extend into) the second insulating layer and extend in the first direction D1. The through plug TP may be electrically connected to a pad portion PAD, and for example, may be electrically connected to the corresponding gate electrodes GE1 and GE2 through the pad portion PAD. The through plug TP may include a conductive material such as metal.

One or more of the first gate electrodes GE1 may be ground selection lines GSL. The ground selection line GSL may control the ground selection transistor among the first transistors LT1 and LT2 described with reference to FIG. 1B. As an example, the ground selection line GSL may be disposed below the stacked structure ST.

Channel holes CH may penetrate the cell array structure CS in the cell array region CAR and the cell array extension region EXR. Each of the channel holes CH may penetrate at least one of the stacked structure ST and the second insulating layer in the first direction D1. As an example, each of the channel holes CH may include a first channel hole CH1 penetrating the first stacked structure ST1 and a second channel hole CH2 penetrating the second stacked structure ST2. For example, a width of each of the first and second channel holes CH1 and CH2 may increase in the second direction D2 and/or the third direction D3 toward the first direction D1. The first and second channel holes CH1 and CH2 may be connected to each other. At a boundary where the first and second channel holes CH1 and CH2 are connected, a diameter of the second channel hole CH2 in the second direction D2 may be smaller than a diameter of the first channel hole CH1. The first and second channel holes CH1 and CH2 may have a step at the boundary where the first and second channel holes CH1 and CH2 are connected to each other, but are not limited thereto.

In the cell array region CAR, the cell vertical structures CVS may penetrate the stacked structure ST in the first direction D1 and conformally cover the channel hole CH. The cell vertical structures CVS may correspond to the memory channel structures 3220 of FIGS. 3 and 4.

In the cell array extension region EXR, dummy vertical structures DVS may penetrate at least one of the stacked structure ST and the second insulating layer ILD2 in the first direction D1 and fill the channel holes CH, respectively. The term “fill” (or “filling,” “filled,” or like terms), as may be used herein, is intended to refer broadly to either completely filling a defined space (e.g., the channel holes CH) or partially filling the defined space; that is, the defined space need not be entirely filled but may, for example, be partially filled or have voids or other spaces throughout. Each of lower surfaces of the cell vertical structure CVS and the dummy vertical structure DVS may have a circular, oval, or bar shape, for example.

Each of the cell vertical structures CVS may include a data storage pattern DSP and a semiconductor pattern SP that sequentially cover an inner sidewall of the channel hole CH, conformally.

The data storage pattern DSP may include a first blocking insulating layer BLK1, a ferroelectric layer FEL, and a second blocking insulating layer BLK2 sequentially stacked on the inner sidewall of the channel hole CH, but is limited thereto. As an example, the data storage pattern DSP may include a charge storage layer (not shown) instead of the ferroelectric layer FEL. In this case, for example, the charge storage layer may include at least one of silicon nitride and silicon oxynitride. When the charge storage layer is provided in place of the ferroelectric layer FEL, Fowler-Nordheim tunneling induced by a voltage difference between the semiconductor pattern SP and the first and second gate electrodes GE1 and GE2 may allow the data storage pattern DSP to store and/or change the data.

The ferroelectric layer FEL may be interposed between the first blocking insulating layer BLK1 and the second blocking insulating layer BLK2. The first blocking insulating layer BLK1, the ferroelectric layer FEL, and the second blocking insulating layer BLK2 may extend between the stacked structure ST and the semiconductor pattern SP along the inner wall of the channel hole CH in the first direction D1.

The data storage pattern DSP may be provided in the plural. The data storage patterns DSP may be spaced apart from each other in the second direction D2 by a separation trench STR which will be described later. As an example, one data storage pattern DSP may conformally cover the channel holes CH. That is, the channel holes CH between the separation trenches STR, which will be described later, adjacent to each other in the second direction D2 may share one data storage pattern DSP.

As an example, the first and second blocking insulating layers BLK1 and BLK2 may include silicon oxide. The ferroelectric layer FEL may include a ferroelectric material that has polarization characteristics due to an electric field applied thereto. As an example, the ferroelectric layer FEL may include at least one of HfO₂, Si-doped HfO₂ (HfSiO₂), Al-doped HfO₂ (HfAlO₂), HfSiON, HfZnO, HfZrO₂, ZrO₂, ZrSiO₂, HfZrSiO₂, ZrSiON, LaAlO, HfDyO₂, and HfScO₂.

The ferroelectric layer FEL may have a spontaneous dipole (electric dipole), that is, spontaneous polarization, as a charge distribution in the memory cell transistors MCT is non-centrosymmetric. The ferroelectric layer FEL has remnant polarization due to a dipole even in the absence of an external electric field. In addition, a direction of polarization may be switched by an external electric field.

That is, the ferroelectric layer FEL may have a positive or negative polarization state, and the polarization state may be variously changed depending on the electric field applied to the ferroelectric layer FEL during a program operation. The polarization state of the ferroelectric layer FEL may be maintained even when the power is turned off, so the three-dimensional semiconductor memory device may operate as a non-volatile memory device. For example, the polarization state of the ferroelectric layer FEL may be determined by the voltage difference between the gate electrodes GE1 and GE2 and the semiconductor pattern SP.

The semiconductor pattern SP may be interposed between the data storage pattern DSP and the back gate plug BPG, which will be described later. As an example, the semiconductor pattern SP may include a semiconductor material doped with an impurity, an intrinsic semiconductor material that is not doped with an impurity, or a polycrystalline semiconductor material.

The semiconductor pattern SP may include a vertical portion VP extending in the first direction D1 in the stacked structure ST and a horizontal portion HP extending further in a horizontal direction than the vertical portion VP on the vertical portion VP. For example, the horizontal portion HP may extend in the second direction D2 or in a direction opposite to the second direction D2 on the vertical portion VP. The vertical portion VP and the horizontal portion HP may form an integrated (i.e., contiguous) shape without an interface.

The vertical portion VP may be provided on a sidewall of the data storage pattern DSP, and the horizontal portion HP may be provided on an upper surface Da of the data storage pattern DSP. The horizontal portion HP may be positioned at a higher level than the upper surface Da of the data storage pattern DSP, relative to the upper surface of the substrate 10 as a reference layer.

The horizontal portion HP may be offset from the channel hole CH. In this specification, when A is offset from B, it means that A is shifted in a certain direction so that A does not overlap B vertically, or a portion of A vertically overlaps B and the other portion of A is shifted in a certain direction so that the other portion of A does not overlap B vertically. The direction in which the horizontal portion HP is offset from the channel hole CH may be subject to many modifications and changes by those skilled in the art. For example, when viewed in a plan view, the horizontal portion HP may have at least one of a circular shape and an oval shape.

A back gate plug BPG may be provided in the channel hole CH. The back gate plug BPG may extend in the first direction D1 in the cell vertical structure CVS. The back gate plug BPG may include a conductive material. As an example, the back gate plug BPG may include a semiconductor material doped with an impurity, an intrinsic semiconductor material that is not doped with an impurity, or a polycrystalline semiconductor material. As another example, the back gate plug BPG may include a metallic material. The back gate plug BPG may correspond to the back gate plug BPG of FIG. 1B.

One back gate plug BPG may be horizontally adjacent to a plurality of gate electrodes GE1 and GE2 in the stacked structure ST.

An upper surface of the back gate plug BPG may be positioned at a higher level than an upper surface STa of the stacked structure ST, relative to the upper surface of the substrate 10. The upper surface of the back gate plug BPG may be positioned at a higher level than an upper surface Va of the vertical portion VP of the semiconductor pattern SP, relative to the upper surface of the substrate 10. As an example, FIG. 6 shows that the upper surface of the back gate plug BPG is positioned substantially the same as the upper surface of the horizontal portion HP of the semiconductor pattern SP, but the inventive concept is not limited thereto.

A back gate insulating layer BGI may be interposed between the semiconductor pattern SP and the back gate plug BPG. As an example, the back gate insulating layer BGI may include an insulating material. The back gate insulating layer BGI may surround (i.e., extend around) and cover side and lower surfaces of the back gate plug BPG. Accordingly, the back gate plug BPG and the semiconductor pattern SP may be spaced apart from each other and electrically insulated by the back gate insulating layer BGI.

The back gate insulating layer BGI may include a lower portion LP surrounding the side and lower surfaces of the back gate plug BPG and an upper portion UP covering the upper surface of the horizontal portion HP of the semiconductor pattern SP. The upper portion UP of the back gate insulating layer BGI may at least partially fill an inside of an opening OP of the back gate plate BPT, which will be described later. The lower portion LP of the back gate insulating layer BGI may be interposed between the semiconductor pattern SP and the back gate plug BPG. The lower portion LP of the back gate insulating layer BGI may cover the upper surface Va of the vertical portion VP of the semiconductor pattern SP. The lower portion LP of the back gate insulating layer BGI may cover the upper surface Da of the data storage pattern DSP.

The back gate plate BPT may be provided on the stacked structure ST. The back gate plate BPT may be provided on an upper surface of the back gate plug BPG and may extend in the second direction D2 and the third direction D3. As an example, the back gate plate BPT may have a plate (i.e., flat or planar) shape extending in the second direction D2 and the third direction D3.

The back gate plate BPT may include a conductive material. As an example, the back gate plate BPT may include a semiconductor material doped with impurities, an intrinsic semiconductor material that is not doped with impurities, or a polycrystalline semiconductor material. As another example, the back gate plate BPT may include a metal material. Accordingly, the back gate plate BPT may be electrically connected to the back gate plug BPG. The back gate plate BPT may correspond to the back gate plate BPT of FIG. 1B.

The back gate plate BPT may include an opening OP offset from the back gate plug BPG at a higher level than the back gate plug BPG, relative to the upper surface of the substrate 10. The opening OP may be offset from the channel hole CH. The opening OP may be offset from the vertical portion VP of the semiconductor pattern SP. The opening OP may vertically overlap the horizontal portion HP of the semiconductor pattern SP. For example, when viewed in a plan view, the opening OP may have at least one of a circular shape and an oval shape. A diameter DT1 of the opening OP may be larger than a diameter DT2 of the horizontal portion HP of the semiconductor pattern SP.

The opening OP may include a plurality of openings OP arranged in a zigzag pattern in the second direction D2. The opening OP may include a plurality of openings OP arranged in a zigzag pattern in the third direction D3. Each of the openings OP may be provided on a corresponding channel hole CH. As an example, some of the openings OP may be offset from the corresponding channel hole CH in the second direction D2, and other portions of the openings OP may be offset from the corresponding channel hole CH in a direction opposite to the direction D2, but is not limited thereto. The direction in which the openings OP are offset from the channel hole CH may be subject to many modifications and changes by those skilled in the art.

Each of the separation trenches STR may extend in the third direction D3. The separation trenches STR may separate the stacked structures ST from each other in the second direction D2. The separation trenches STR may separate the back gate plates BPT from each other in the second direction D2. Accordingly, one back gate plate BPT may be electrically connected to the back gate plugs BPG in the channel holes CH interposed between the separation trenches STR adjacent to each other in the second direction D2. Each of the separation trenches STR may extend from the cell array region CAR toward the cell array extension region EXR.

The first separation patterns SS1 may at least partially fill interiors of the separation trenches STR. The first separation patterns SS1 may correspond to the separation structures 3230 of FIG. 3. For example, upper surfaces of the first separation patterns SS1 may be positioned at substantially the same level as upper surfaces of the back gate plates BPT. The first separation patterns SS1 may include, for example, at least one of silicon oxide, silicon nitride, silicon oxynitride, and a low dielectric material.

An upper insulating layer UIL may be provided on the stacked structure ST. Specifically, the upper insulating layer UIL may cover the upper surface of the back gate plate BPT. As an example, the upper insulating layer UIL may include a plurality of insulating layers having a multilayer structure.

A selection line SSL may be provided in the upper insulating layer UIL. The selection line SSL may extend in the second direction D2 and the third direction D3 on the back gate plate BPT. The selection line SSL may include conductive material. As an example, the selection line SSL may control a string selection transistor among the second transistors UT1 and TU2 described with reference to FIG. 1B. The selection line SSL may be provided in the plural. A plurality of selection lines SSL may be adjacent to each other in the second direction D2.

Each of the second separation patterns SS2 may extend in the third direction D3 on the first separation pattern SS1 and may penetrate the selection line SSL. The second separation pattern SS2 may include an insulating material. The second separation patterns SS2 may space the selection lines SSL apart from each other in the second direction D2 and electrically insulate the selection lines SSL.

A selection channel structure ECS may be provided on the horizontal portion HP of the semiconductor pattern SP. The selection channel structure ECS may be interposed in the opening OP and may vertically overlap the opening. The selection channel structure ECS may penetrate the selection line SSL and may extend into the opening OP of the back gate plate BPT. The selection channel structure ECS may penetrate the upper portion UP of the back gate insulating layer BGI that at least partially fills the interiors of the opening OP and may be in contact with the horizontal portion HP of the semiconductor pattern SP. As an example, an upper portion of the horizontal portion HP of the semiconductor pattern SP may be recessed by the selection channel structure ECS.

The selection channel structure ECS may include a selection insulating layer ED and a selection channel layer EC that conformally cover an inner side of the selection line SSL, a selection internal insulating layer EI surrounded by the selection channel layer EC, and a selection channel pad EP on the selection internal insulating layer EI.

The selection insulating layer ED and the selection internal insulating layer EI may include an insulating material. The selection insulating layer ED may include a plurality of insulating layers. As an example, the selection insulating layer ED may include at least one of silicon oxide and silicon nitride. As an example, the selection internal insulating layer EI may have a pillar shape.

The selection channel layer EC and the selection channel pad EP may include a conductive material. As an example, the selection channel layer EC and the selection channel pad EP may include a semiconductor material doped with impurities, an intrinsic semiconductor material that is not doped with an impurity, or a polycrystalline semiconductor material. The selection channel layer EC may penetrate the selection line SSL and may extend into the opening OP, thereby being in contact with the horizontal portion HP of the semiconductor pattern SP. Accordingly, the selection channel layer EC may be electrically connected to the semiconductor pattern SP. Simultaneously, the selection channel pad EP may be electrically connected to the semiconductor pattern SP through the selection channel layer EC. The selection channel pad EP may be surrounded by an upper portion of the selection channel layer EC.

The bit line BL may extend in the second direction D2 on the selection channel structure ECS. The bit line BL may include a conductive material such as metal. The bit line BL may correspond to the bit line 3240 in FIGS. 3 and 4.

A bit line contact BLC may be interposed between the bit line BL and the selection channel structure ECS. As an example, the bit line contact BLC may be in contact with the selection channel pad EP. The bit line contact BLC may include a conductive material such as metal. The bit line BL may be electrically connected to the selection channel pad EP and the selection channel layer EC through the bit line contact BLC. That is, the bit line BL may be electrically connected to the selection channel structure ECS through the bit line contact BLC. Accordingly, the bit line BL may be electrically connected to the semiconductor pattern SP through the selection channel structure ECS.

A protective layer PL may be provided on the entire surface the cell array structure CS. The protective layer PL may be a single layer made of a single material or a composite layer containing two or more materials. As an example, the protective layer PL may have a structure in which polyimide-based materials such as silicon oxide, silicon nitride, and photo sensitive polyimide (PSPI) are sequentially stacked, but is not limited thereto. Although not shown, the protective layer PL may have an opening that exposes portion of the input/output pads. As an example, although not shown, upper wirings may be provided in the protective layer PL and electrically connected to the cell array structure CS, the back gate plate BPT, and the selection line SSL, but are not limited thereto. As another example, the back gate plate BPT may not be electrically connected to the upper wiring, but may be electrically connected to the peripheral circuit structure PS through a separate contact.

According to the inventive concept, the back gate plug BPG may be provided in the cell vertical structure CVS covering the interior of the channel hole CH. During a program operation for a selected memory cell of a selected cell string, unselected word lines of unselected memory cells may be floated, or even when a ground voltage is applied to the word lines, a back gate voltage may be applied to the back gate plug BPG, thereby forming an inversion region in the vertical portion VP of the semiconductor pattern SP. Accordingly, the ground voltage applied to the bit line BL may be transmitted to the inversion region in the vertical portion VP of the semiconductor pattern SP. As a result, a polarity of the ferroelectric layer FEL may change due to a difference between the program voltage applied to the selected word line of the selected memory cell and the ground voltage in the vertical portion VP of the semiconductor pattern SP, and data may be written in the selected memory cell.

In the case of the inventive concept, to form the inversion region in the vertical portion VP of the semiconductor pattern SP, additional voltage applied to the unselected word lines may not be necessary. Accordingly, the polarity of the ferroelectric layer FEL may not change due to the additional voltage applied to the unselected word lines, and data may not be unintentionally written or erased in the unselected memory cells. As a result, disturbance occurring during program operation of the three-dimensional semiconductor memory device may be prevented, and reliability of the three-dimensional semiconductor memory device may be improved.

According to the inventive concept, the back gate plate BPT may extend in the second direction D2 and the third direction D3 on the stacked structure ST. The back gate plate BPT may be in contact with and electrically connected to the back gate plugs BPG. Accordingly, a process of forming the back gate plate BPT on the stacked structure ST and connecting the back gate plate BPT to the back gate plugs BPG may be easier than a process of forming the back gate plate BPT under the stacked structure ST and connecting the back gate plate BPT to the back gate plugs BPG. As a result, productivity of three-dimensional semiconductor memory devices may be improved.

In addition, the back gate plate BPT may have the openings OP. Accordingly, the bit line BL may be electrically connected to the semiconductor patterns SP through the selection channel structure ECS disposed inside each of the openings OP. As a result, even though the back gate plate BPT is provided on the stacked structure ST, the process of electrically connecting the bit line BL and the semiconductor patterns SP on the stacked structure ST may become easy. Accordingly, the productivity of the three-dimensional semiconductor memory device may be improved.

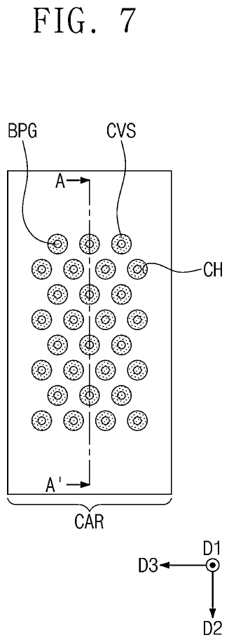

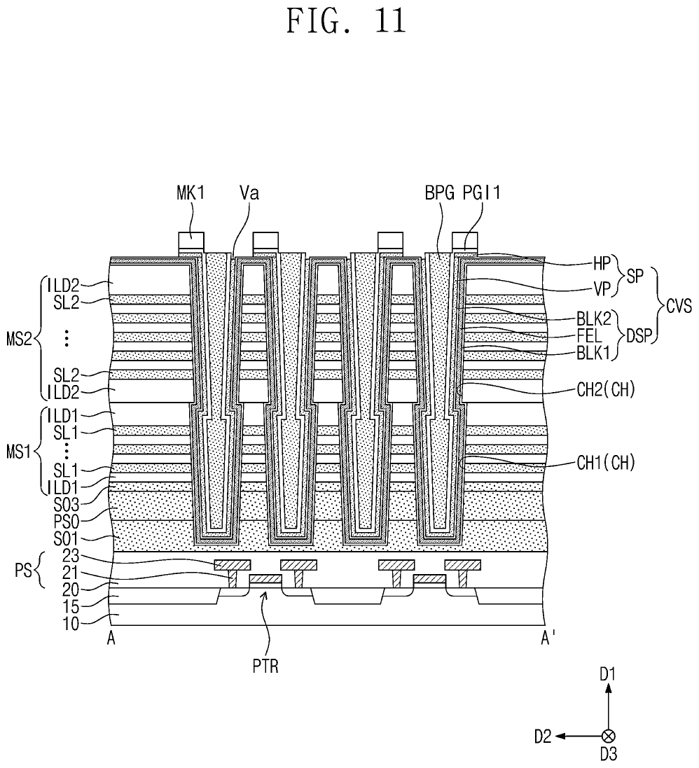

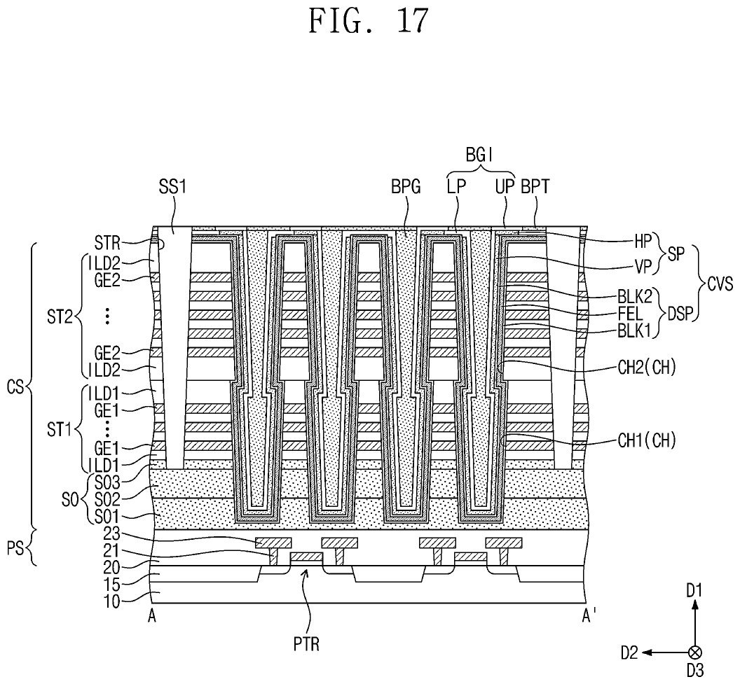

Hereinafter, a method of manufacturing a three-dimensional semiconductor memory device according to some embodiments of the inventive concept will be described with reference to FIGS. 7 to 19. To simplify the explanation, description of content that overlaps with the above-described content will be omitted, and the explanation will focus on the differences from the above-described content.

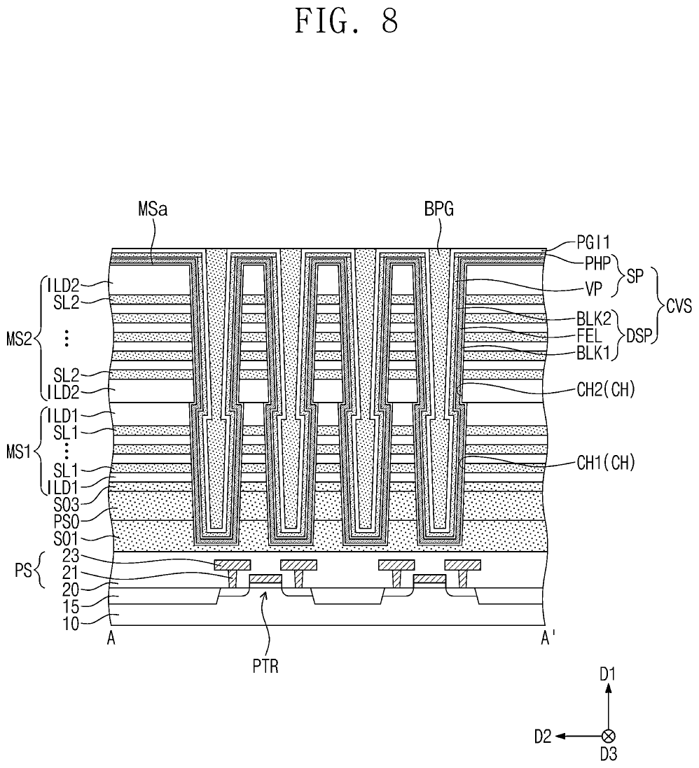

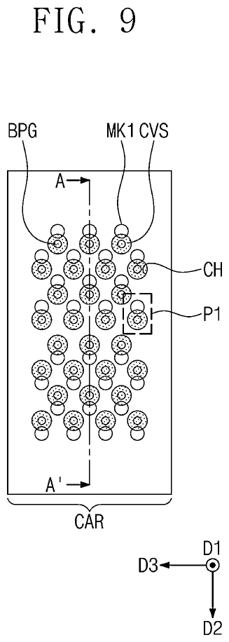

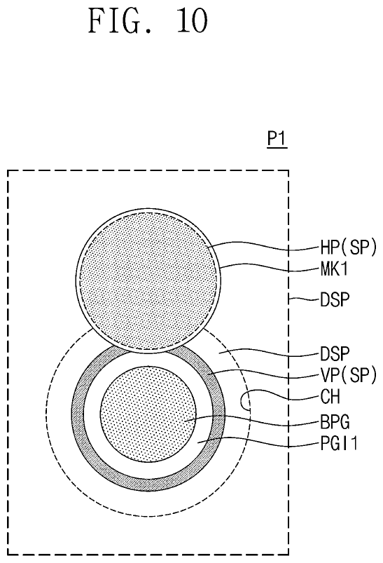

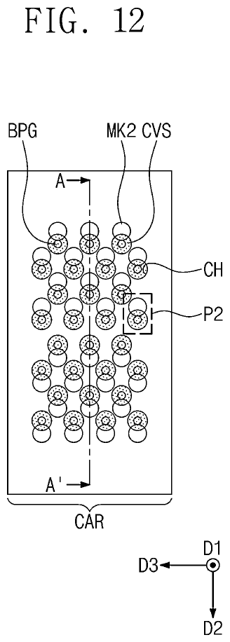

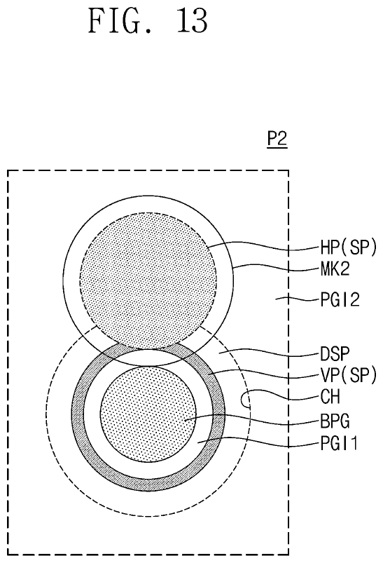

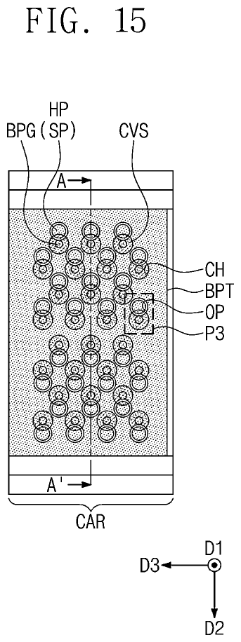

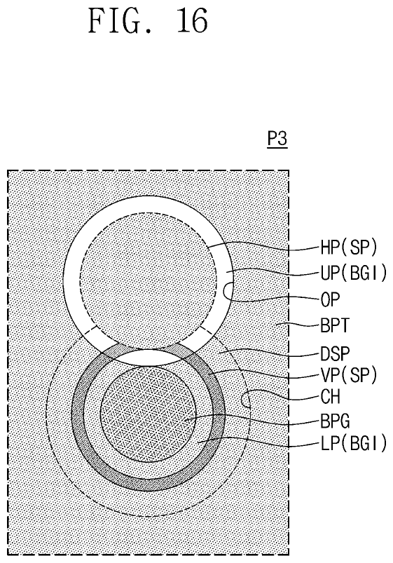

FIGS. 7 to 19 are diagrams schematically depicting intermediate processes in an example method of manufacturing a three-dimensional semiconductor memory device according to embodiments of the inventive concept. Specifically, FIGS. 7, 9, 12, 15, and 18 are plan views corresponding to the cell array region CAR of FIG. 5, respectively. FIG. 10 is an enlarged view corresponding to region ‘P1’ in FIG. 9. FIG. 13 is an enlarged view corresponding to region ‘P2’ in FIG. 12. FIG. 16 is an enlarged view corresponding to region ‘P3’ in FIG. 15. FIGS. 8, 11, 14, 17, and 19 are cross-sectional views taken along line A-A′ of FIGS. 7, 9, 12, 15, and 18, respectively.

Referring to FIGS. 7 and 8, a peripheral circuit structure PS may be formed on a substrate 10. Forming the peripheral circuit structure PS may include forming a device isolation layer 15 inside the substrate 10, forming peripheral transistors PTR on an active region of the substrate 10 defined by the device isolation layer 15, and forming peripheral contact plugs 21 electrically connected to the peripheral transistors PTR, peripheral circuit wirings 23, and a first insulating layer 20 covering them.

A first source layer SO1, a preliminary source layer (not shown), and a third source layer SO3 may be sequentially formed on the first insulating layer 20. As an example, the preliminary source layer may include an insulating material. A first mold structure MS1 may be formed on the third source layer SO3. The first mold structure MS1 may include first interlayer insulating layers ILD1 and first sacrificial layers SL1 that are alternately stacked in the first direction D1 (i.e., vertically stacked). The first interlayer insulating layers ILD1 and the first sacrificial layers SL1 may include different insulating materials. As an example, the first interlayer insulating layers ILD1 may include silicon oxide, and the first sacrificial layers SL1 may include silicon nitride.

A first channel hole CH1 may be formed to penetrate (i.e., extend in) the first interlayer insulating layers ILD1 and the first sacrificial layers SL1 in a first direction D1. In this case, components such as dummy holes DH (in FIG. 5) and through holes TH (in FIG. 5) may be formed together, but are not limited thereto.

A second mold structure MS2 may be formed on the first mold structure MS1. The second mold structure MS2 may include second interlayer insulating layers ILD2 and second sacrificial layers SL2 that are alternately stacked in the first direction D1. The characteristics of the second interlayer insulating layers ILD2 and the second sacrificial layers SL2 may be the same/similar to those of the first interlayer insulating layers ILD1 and the first sacrificial layers SL1.

Thereafter, a second channel hole CH2 may be formed to penetrate the second interlayer insulating layers ILD2 and the second sacrificial layers SL2 in the first direction D1. In this case, components such as dummy holes DH (in FIG. 5) and through holes TH (in FIG. 5) may be formed together, but are not limited thereto. The first and second channel holes CH1 and CH2 may constitute a channel hole CH.

A cell vertical structure CVS and a dummy vertical structure DVS (in FIG. 5) may be formed to at least partially fill the channel holes CH and dummy channel holes DH (in FIG. 5), respectively. Forming the cell vertical structure CVS may include sequentially forming a data storage pattern DSP and a semiconductor pattern SP conformally in the channel hole CH. The data storage pattern DSP and a preliminary horizontal portion PHP of the semiconductor pattern SP may be formed to cover an upper surface MSa of the second mold structure MS2.

A first preliminary back gate insulating layer PGI1 may be formed to conformally cover the vertical portion VP and the preliminary horizontal portion PHP of the semiconductor pattern SP. Thereafter, a back gate plug BPG may be formed to fill the remaining portions of the channel holes CH.

Referring to FIGS. 9 to 11, a first mask pattern MK1 may be formed on the second mold structure MS2. Specifically, the first mask pattern MK1 may be formed on an upper surface of the first preliminary back gate insulating layer PGI1. The first mask pattern MK1 may be provided in the plural. Each of the first mask patterns MK1 may be provided on a corresponding channel hole CH, and may be offset from the corresponding channel hole CH a certain direction (e.g., the second direction D2 or a direction opposite to the second direction D2). The first mask patterns MK1 may be arranged in a zigzag pattern in the second direction D2 and the third direction D3. When viewed in a plan view, the first mask pattern MK1 may have at least one of a circular shape and an oval shape.

Thereafter, a first removal process may be performed on the first preliminary back gate insulating layer PGI1 using the first mask pattern MK1 as a mask. Accordingly, a portion of the preliminary horizontal portion PHP of the semiconductor pattern SP may be exposed to the outside, and an upper portion of the back gate plug BPG may be exposed to the outside.

Thereafter, using the first mask pattern MK1 again as a mask, a second removal process may be performed on the exposed portion of the preliminary horizontal portion PHP of the semiconductor pattern SP and the exposed upper portion of the back gate plug BPG. Accordingly, one semiconductor pattern SP covering the channel holes CH may be divided into a plurality of semiconductor patterns SP. During the second removal process, the exposed portion of the preliminary horizontal portion PHP of the semiconductor pattern SP may be completely removed, and the other unexposed portion of the preliminary horizontal portion PHP may form a horizontal portion HP described with reference to FIGS. 5 and 6. During the second removal process, the upper surface of the data storage pattern DSP and the upper surface Va of the vertical portion VP of the semiconductor pattern SP may be exposed to the outside.

Referring to FIGS. 12 to 14, a second preliminary back gate insulating layer PGI2 may be formed on the second mold structure MS2. The second preliminary back gate insulating layer PGI2 may be formed to cover the exposed upper surface of the data storage pattern DSP and the exposed upper surface of the vertical portion VP of the semiconductor pattern SP. The second preliminary back gate insulating layer PGI2 may be formed to be horizontally coplanar with the first preliminary back gate insulating layer PGI1.

A second mask pattern MK2 may be formed on the second mold structure MS2. Specifically, the second mask pattern MK2 may be formed on the horizontal portion HP of the semiconductor pattern SP. For example, when viewed in a plan view, a shape of the second mask pattern MK2 may be the same as or similar to a shape of the first mask pattern MK1 described with reference to FIGS. 9 to 11. The second mask pattern MK2 may be provided in the plural. An arrangement manner of the second mask patterns MK2 may be the same as or similar to an arrangement manner of the first mask patterns MK1 described with reference to FIGS. 9 to 11. A diameter of the second mask pattern MK2 in the second direction D2 or third direction D3 may be larger than a diameter of the horizontal portion HP of the semiconductor pattern SP.

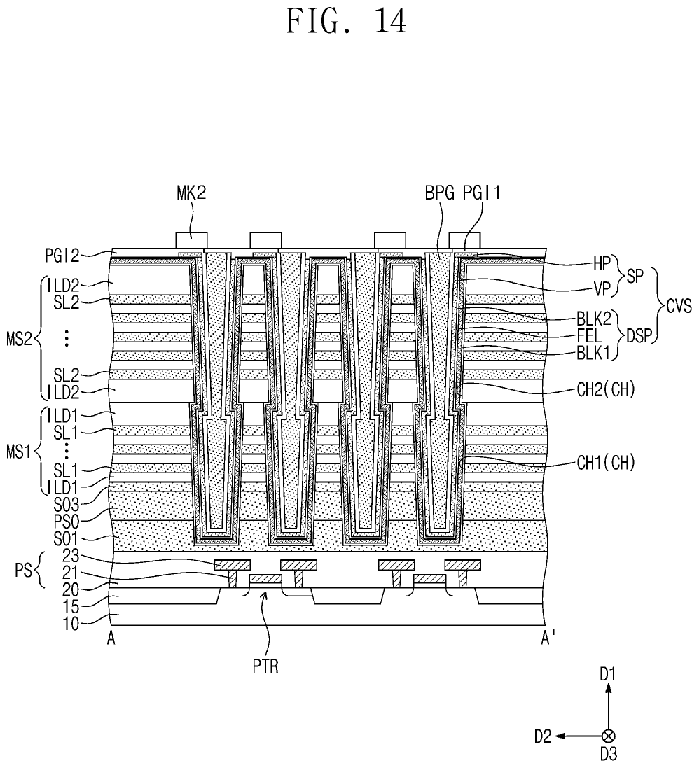

Referring to FIGS. 15 to 17, a removal process may be performed on a portion of the second preliminary back gate insulating layer PGI2 (see FIG. 14) using the second mask pattern MK2 as a mask. During the removal process, the remainder of the second preliminary back gate insulating layer PGI2 may form the back gate insulating layer BGI together with the first preliminary back gate insulating layer PGI1.

The back gate plate BPT may be formed in a region where the portion of the second preliminary back gate insulating layer PGI2 (see FIG. 14) has been removed. For example, an upper surface of the back gate plate BPT may be horizontally coplanar with an upper surface UP of the back gate insulating layer BGI. When forming the back gate plate BPT, the back gate plate BPT may include an opening OP formed by the upper surface UP of the back gate insulating layer BGI.

A separation trench STR may be formed to penetrate the third source layer SO3, the first and second mold structures MS1 and MS2 (see FIG. 14), the data storage pattern DSP, and the back gate plate BPT. The second source layer SO2 may be formed to replace the preliminary source layer PSO exposed by the separation trench STR. The first to third source layers SO1, SO2, and SO3 may form the source layer SO.

Afterwards, an isotropic etching process using the separation trench STR as a path may be performed, and the first and second sacrificial layers SL1 and SL2 may be removed. The first and second gate electrodes GE1 and GE2 may be formed in the places where the first and second sacrificial layers SL1 and SL2 were removed, and the stacked structure ST may be formed therethrough. The first separation pattern SS1 may be formed to at least partially fill the separation trench STR. The through plugs TP (in FIG. 5) may be formed to at least partially fill the through holes TH (in FIG. 5).

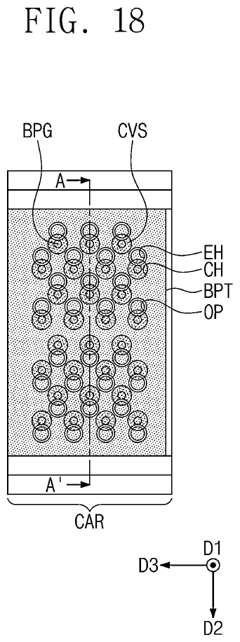

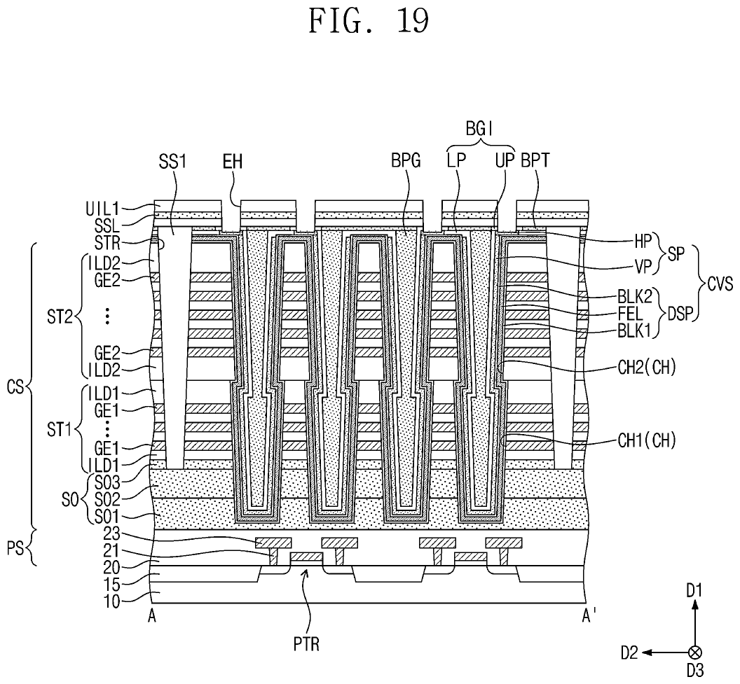

Referring to FIGS. 18 and 19, a first upper insulating layer UIL1 may be formed on the back gate plate BPT. A selection line SSL may be formed in the first upper insulating layer UIL1.

Thereafter, a selection hole EH may be formed to penetrate the first upper insulating layer UIL1 and the selection line SSL. The selection hole EH may be formed to penetrate the selection line SSL and extend further into the opening OP. As an example, an upper portion of the horizontal portion HP of the semiconductor pattern SP may be recessed by the selection hole EH. The selection hole EH may be offset from the channel hole CH.

The selection hole EH may be formed in the plural. Each of the selection holes EH may be formed to vertically overlap the horizontal portion HP of the corresponding semiconductor pattern SP.

Referring again to FIGS. 5 and 6, a selection insulating layer ED and a selection channel layer EC may be formed to sequentially cover an inner wall of the selection hole EH conformally. The selection internal insulating layer EI may be formed to at least partially fill the inside of the selection hole EH, and the selection channel pad EP may be formed to fill the remainder of the selection hole EH. The selection insulating layer ED, the selection channel layer EC, the selection internal insulating layer EI, and the selection channel pad EP may constitute a selection channel structure ECS.

A second separation pattern SS2 may be formed to penetrate the selection line SSL. Accordingly, the selection line SSL may be divided into selection lines SSL spaced apart in the second direction D2.

Thereafter, a second upper insulating layer (not shown) may be formed on the first upper insulating layer UIL1. The second upper insulating layer may form the upper insulating layer UIL together with the first upper insulating layer UIL1.

A bit line contact BLC may be formed to penetrate the upper insulating layer UIL and be in contact with the selection channel pad EP. The bit line BL may be formed to extend in the second direction D2 on the bit line contact BLC. Thereafter, a protective layer PL may be formed to cover the cell array structure CS.

According to the inventive concept, the back gate plug may be provided in the cell vertical structure covering the interior of the channel hole. Accordingly, the disturbance phenomenon occurring during the program operation in the unselected memory cell may be prevented. As a result, the reliability of the three-dimensional semiconductor memory device may be improved.

According to the inventive concept, the back gate plate may extend in the second and third directions on the stacked structure. The back gate plate may be in contact with and may be electrically connected to the back gate plugs. Accordingly, the process of forming the back gate plate on the stacked structure and connecting the back gate plate to the back gate plugs may be easier than the process of forming the back gate plate under the stacked structure and connecting the back gate plate to the back gate plugs. As a result, the productivity of three-dimensional semiconductor memory devices may be improved.

Additionally, the back gate plate may have the openings. Accordingly, the bit line may be electrically connected to the semiconductor patterns through the selection channel structure disposed inside each of the openings. As a result, despite the back gate plate being provided on the stacked structure, the process of electrically connecting the bit lines and semiconductor patterns on the stacked structure may be facilitated. Accordingly, the productivity of the three-dimensional semiconductor memory device may be improved.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A three-dimensional semiconductor memory device, comprising:
a substrate;
a stacked structure including gate electrodes stacked on the substrate in a first direction perpendicular to a lower surface of the substrate;
a semiconductor pattern extending in the stacked structure in the first direction;
a back gate plug extending in the first direction in the semiconductor pattern;
a back gate plate extending on an upper surface of the back gate plug in a second direction and a third direction parallel to the lower surface of the substrate, the third direction intersecting the second direction, the back gate plate having an opening therein;
a bit line on the back gate plate; and
a selection channel structure electrically connecting the bit line and the semiconductor pattern,
wherein the selection channel structure is in the opening.

2. The three-dimensional semiconductor memory device of claim 1, wherein the opening includes a plurality of openings arranged in a zigzag pattern in the second direction.

3. The three-dimensional semiconductor memory device of claim 1, further comprising a channel hole extending in the stacked structure in the first direction,
wherein the semiconductor pattern is in the channel hole, and
wherein the opening is offset from the channel hole in the first direction.

4. The three-dimensional semiconductor memory device of claim 1, further comprising a selection line on the back gate plate,
wherein the selection channel structure extends in the selection line in the first direction and extends into the opening.

5. The three-dimensional semiconductor memory device of claim 1, wherein the semiconductor pattern includes a vertical portion extending in the first direction in the stacked structure and a horizontal portion extending further in a horizontal direction than the vertical portion, on the vertical portion, the horizontal direction being any direction in a plane defined by the second and third directions.

6. The three-dimensional semiconductor memory device of claim 5, wherein the horizontal portion of the semiconductor pattern has a shape of at least one of a circular shape and an oval shape, when viewed in a plan view.

7. The three-dimensional semiconductor memory device of claim 5, wherein the opening at least partially vertically overlaps the horizontal portion of the semiconductor pattern.

8. The three-dimensional semiconductor memory device of claim 5, wherein a diameter of the opening is larger than a diameter of the horizontal portion of the semiconductor pattern.

9. The three-dimensional semiconductor memory device of claim 5, further comprising a channel hole extending in the stacked structure in the first direction,
wherein the semiconductor pattern is in the channel hole, and
wherein the horizontal portion of the semiconductor pattern is horizontally offset from the channel hole.

10. The three-dimensional semiconductor memory device of claim 1, further comprising a ferroelectric layer extending in the first direction between the stacked structure and the semiconductor pattern.

11. A three-dimensional semiconductor memory device, comprising:
a substrate;
a stacked structure including gate electrodes stacked on the substrate in a first direction perpendicular to a lower surface of the substrate;
a ferroelectric layer and a semiconductor pattern extending in the stacked structure in the first direction;
a back gate plug extending in the first direction in the semiconductor pattern; and
a back gate plate extending in a second direction and a third direction parallel to the lower surface of the substrate, on an upper surface of the back gate plug,
wherein the semiconductor pattern includes a vertical portion extending in the first direction and a horizontal portion extending further in a horizontal direction than the vertical portion, on the vertical portion, the horizontal direction being any direction in a plane defined by the second and third directions, and
wherein the back gate plate includes an opening that at least partially vertically overlaps the horizontal portion of the semiconductor pattern.

12. The three-dimensional semiconductor memory device of claim 11, wherein the horizontal portion of the semiconductor pattern has a shape of at least one of a circular shape and an oval shape, when viewed in a plan view.

13. The three-dimensional semiconductor memory device of claim 11, further comprising a channel hole extending in the stacked structure in the first direction,
wherein the semiconductor pattern is in the channel hole, and
wherein the horizontal portion of the semiconductor pattern is horizontally offset from the channel hole.

14. The three-dimensional semiconductor memory device of claim 11, wherein a diameter of the opening is larger than a diameter of the horizontal portion of the semiconductor pattern.

15. The three-dimensional semiconductor memory device of claim 11, further comprising:
a selection line on the stacked structure; and
a selection channel layer extending in the selection line in the first direction and extending into the opening.

16. The three-dimensional semiconductor memory device of claim 15, wherein the selection channel layer is in contact with the horizontal portion of the semiconductor pattern.

17. The three-dimensional semiconductor memory device of claim 11, wherein the horizontal portion of the semiconductor pattern is at a higher level than an upper surface of the stacked structure, relative to the lower surface of the substrate as a reference layer.

18. An electronic system, comprising:
a three-dimensional semiconductor memory device; and
a controller electrically connected to the three-dimensional semiconductor memory device through at least one input/output pad and controlling the three-dimensional semiconductor memory device,
wherein the three-dimensional semiconductor memory device includes:
a substrate;
a stacked structure including gate electrodes stacked on the substrate in a first direction perpendicular to a lower surface of the substrate;
a semiconductor pattern extending in the stacked structure in the first direction;
a back gate plug extending in the first direction in the semiconductor pattern;
a back gate plate extending on an upper surface of the back gate plug in a second direction and a third direction parallel to the lower surface of the substrate, and having an opening therein;
a bit line on the back gate plate; and
a selection channel structure electrically connecting the bit line and the semiconductor pattern, and
wherein the selection channel structure is in the opening.

19. The electronic system of claim 18, further comprising a selection line on the back gate plate,
wherein the selection channel structure extends in the selection line in the first direction and extends into the opening.

20. The electronic system of claim 18, wherein the semiconductor pattern includes a vertical portion extending in the first direction in the stacked structure and a horizontal portion extending further in a horizontal direction than the vertical portion, on the vertical portion, the horizontal direction being any direction in a plane defined by the second and third directions, and
wherein the opening at least partially vertically overlaps the horizontal portion of the semiconductor pattern.
